(19) United States
(12) Patent Application Publication
(10) Pub. No.: US 2005/0046022 A1
(43) Pub. Date: Mar. 3, 2005

(54) Semiconductor devices integrated with wafer-level packaging

(75) Inventor: Martin Alter, Los Altos, CA (US)

Correspondence Address: Eugene H. Valet;ValetParents, 314 10th Ave. South, Edmonds, WA, 98020-3312, US

(73) Assignee: MICREL, INCORPORATED, San Jose, CA (US)

(21) Appl. No.: 10/648,016

(22) Filed: Aug. 26, 2003

(51) Int. Cl. H01L 23/48

(52) U.S. Cl. 257/734

(57) ABSTRACT

Active circuit elements for semiconductor devices are integrated with chip-scale bump-out beams. In some embodiments, regions of the beam itself are employed as part of an active element. The bump-out beam is employed to construct selected components of the active circuit elements such as a resistor, an inductor, a capacitor, or an antenna for the semiconductor device.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO AN APPENDIX

Not applicable.

### BACKGROUND

1. Technical Field

This disclosure relates generally to integrated circuits (also referred to in the art as an “IC,” a “chip,” or a “die”) and, more particularly to a use of chip-scale, wafer-level packaging (“WLP”) in forming active devices.

2. Description of Related Art

Semiconductor integrated circuits in the state of the art have been able to pack millions of circuit elements into a relatively small die, e.g., having lateral area footprint, e.g., a ¼″ by ¼″. Most ICs are designed with input-output (“I/O”) pads located along the periphery of the chip; some requiring hundreds of such pads. These pads are then wire-bonded to connect the IC to the macro-world of a printed wire board (“PWB”), also known as printed circuit board (“PCB”), and to the surrounding discrete elements and other IC electronics on the board. This conventional perimeter-lead surface mount technology (“SMT”) for complex circuitry with appropriate interconnects often requires a chip carrier several times greater in size than the chip itself.

For mobile appliances—e.g., cellular telecommunications products, portable digital assistants (“PDA”), notebook computers, and the like—or applications where physical space for computers and instrumentations is extremely valuable—e.g., aircraft, space shuttles, and the like—individual component size and weight are factors which are critical to successful design. Thus, there is a conflict between a higher density of IC elements on the chip with attendant higher inpuvoutput (“I/O”) needs and a simultaneous demands for continuing miniaturization with increased functionality.

Wafer-level packaging, wherein a single IC die and its mounting package are manufactured and tested on a multi-die wafer produced by the IC manufacturer prior to singulation into individual chips, offers many advantages to the chip manufacturer. One WLP solution known in the art is generally referred to in the art as chip-scale packages (“CSP”). Chip-scale packaging technology, where the peripheral pad configuration is redistributed, provides die-sized packaging, allowing more condensed PCB patterns, also referred to in the art as “land patterns” where elements have a specific area “footprint.”

Exemplary, conventional, chip-scale technology is demonstrated by FIGS. 1A and 1B, taken from Semiconductor International magazine, Oct. 2000, pp. 119-128, “Wafer-Level Packaging Has Arrived,” by Dr. Philip Garrou, illustrating the process 100, FIG. 1A, and resultant structure 102, FIG. 1B, for chip-scale packaging I/O redistribution. As shown in FIG. 1A, IC die peripheral I/O pads 103 are redistributed to bumps 107 via known manner processes, including a “Metallization” step 105 from pads 103. The process continues to an I/O bump formation step wherein the bumps 107 are located inwardly from the chip periphery. Conductive material (such as a metal, e.g., copper) beams 109—also referred to hereinafter as “bump-out beams”—are lithographically defined superjacent the chip passivation layer 111 (e.g., a plasma nitride or the like) and within a protective-covering-stress-absorbing material (e.g., resin, polyimide, or the like) 113, providing a conventional wisdom IC, “Silicon,” with chip-scale packaging structure as shown in FIG. 1B. A variety of implementations are described by Garrou. In current wafer-level packaging, these additional layers of the chip-scale package are generally are so formed on the wafer after the die fabrication is completed, yielding a plurality of packaged die on the wafer, which has many advantages for the manufacturer. A thereafter singulated die with chip-scale package 115 with eight bumps 107 is illustrated in FIG. 1C, showing that the total footprint is essentially the same as the die area. The present invention relates to further discoveries in this regard.

Many publications describe the details of common techniques used in the fabrication of integrated circuits that can be generally employed in the fabrication of complex, three-dimensional, IC structures; see e.g., Silicon Processes, Vol. 1-3, copyright 1995, Lattice Press, Lattice Semiconductor Corporation (assignee herein), Hillsboro, Oreg. Moreover, the individual steps of such a process can be performed using commercially available IC fabrication machines. The use of such machines and common fabrication step techniques will be referred to hereinafter as simply: “in a known manner.” As specifically helpful to an understanding of the present invention, approximate technical data are disclosed herein based upon current technology; future developments in this art may call for appropriate adjustments as would be apparent to one skilled in the art.

### BRIEF SUMMARY

A basic aspect of the invention generally provide for integration of WLP bump-out beams into IC device elements.

In one exemplary embodiment, there is provided an integrated circuit structure including: a circuit die; at least one input-output pad for connecting to said circuit die; wafer-level packaging including an electrically conductive material beam and at least one active circuit element wherein the active circuit element integrates therein at least a segment of said beam.

In another exemplary embodiment, there is provided a wafer-level packaged integrated circuit device including: a circuit die having at least one input-output pad; a wafer-level package including a dielectric material layer superjacent said die and a conductive material bump-out beam encapsulated in said layer and leading to a connector bump on an external surface of said dielectric material layer; and a sense resistor integrated into said wafer-level package, using a predetermined segment of said beam as a resistor body and having a pair of leads from said segment through said dielectric material layer to said surface.

In another exemplary embodiment there is provided a wafer-level packaged integrated circuit device including: a circuit die having at least one input-output pad and a top metal layer; a wafer-level package including a dielectric material layer superjacent said die and a conductive material beam encapsulated in said dielectric material layer and leading to a connector bump on an external surface of said dielectric material layer; and an ESD protection capacitor integrated into said top metal layer, using a predetermined segment of said beam as a first plate and having a grounded second plate embedded in said dielectric material layer proximate said segment.

In another exemplary embodiment there is provided a wafer-level packaged integrated circuit device including: a circuit die having at least one input-output pad and a top metal layer; a wafer-level package including a dielectric material layer superjacent said die and a conductive material beam encapsulated in said dielectric material layer and leading to a connector bump on an external surface of said dielectric material layer; and an inductor integrated into said top metal layer, having a first tap comprising a segment of said beam, a coil embedded in said top metal layer having a proximate end electrically connected to said first tap and a second distal end electrically connecting to said circuit die.

In another exemplary embodiment there is provided a wafer-level packaged integrated circuit device including: a circuit die having at least one input-output (I/O) pad; a wafer-level package including a dielectric material layer superjacent said die and a conductive material beam encapsulated in said dielectric material layer, said beam having a first end electrically connected to said I/O pad and having a geometric shape and size forming an antenna for said die.

In another exemplary embodiment there is provided a method for fabricating an input-output (I/O) active device for an integrated circuit die having a top metal layer and using wafer-level packaging, said packaging including a dielectric material layer superjacent said die and a conductive material bump-out beam encapsulated in said layer and leading to a connector bump on an external surface of said dielectric material layer, the method including: forming at least a part of said active device in a dielectric said top metal layer; forming a segment of said beam as another integral part of said active device; and forming an electrical connection between said part of said active device and said segment.

The foregoing summary is not intended to be inclusive of all aspects, objects, advantages and features of the present invention nor should any limitation on the scope of the invention be implied therefrom. This Brief Summary is provided in accordance with the mandate of 37 C.F.R. 1.73 and M.P.E.P. 608.01(d) merely to apprise the public, and more especially those interested in the particular art to which the invention relates, of the nature of the invention in order to be of assistance in aiding ready understanding of the patent in future searches.

### BRIEF DESCRIPTION OF THE DRAWINGS

FIG. 1A (Conventional) is a schematic chip-scale process flow diagram.

FIG. 1B (Conventional) is a partial cross section, elevation view, of a chip-scale I/O redistribution die formed in accordance with the process as shown in FIG. 1A.

FIG. 1C (Conventional) is a schematic perspective view of a singulated wafer-level chip-scale package and attached die resultant from a process and fabrication as shown in FIGS. 1A and 1B.

FIG. 2 in accordance with a first exemplary embodiment of the present invention is an electrical circuit diagram for a WLP scale electrostatic discharge protection at an IC input-output pad.

FIG. 3 in accordance with a first exemplary embodiment of the present invention is an elevation view schematic diagram for a WLP scale IC capacitor element implementation for the circuit diagram of FIG. 2.

FIG. 4 in accordance with a second exemplary embodiment of the present invention is an elevation view schematic diagram for a WLP scale sense resistor element implementation.

FIG. 5 in accordance with a third exemplary embodiment of the present invention is an elevation view schematic diagram for WLP scale inductor element implementation.

FIG. 6 in accordance with a fourth exemplary embodiment of the present invention is an elevation view schematic diagram, with a rotated, blow-up, section, for a WLP scale antenna implementation.

Like reference designations represent like features throughout the drawings. The drawings in this specification should be understood as not being drawn to scale unless specifically annotated as such.

### DETAILED DESCRIPTION

The present invention uses chip-scale, wafer level packaging as an integral part of active elements used of an integrated circuit die.

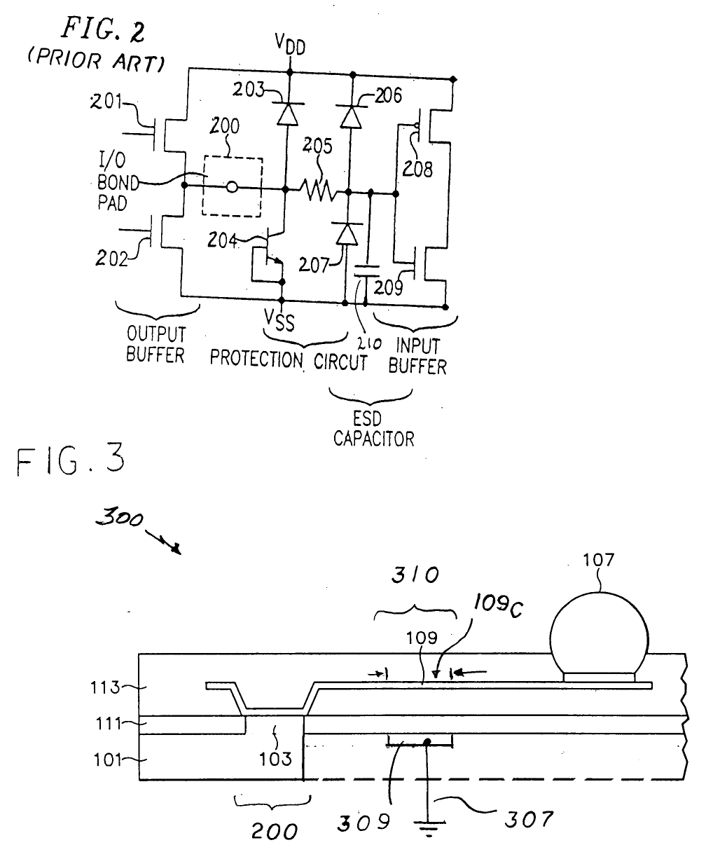

One exemplary embodiment relates to forming resistor elements. Integrated circuits are susceptible to damage from electrostatic discharges (“ESD”) onto an input-output (“I/O”) pad. Such ESD events can achieve approximately 200 volts to 500 volts. FIG. 2 (Prior Art) shows a typical I/O circuit 202 for a MOS (metal oxide semiconductor) chip. An I/O Bond Pad 200 is shown employing an Output Buffer, transistors 201, 202, or an Input Buffer, transistors 208, 209. A typical ESD Protection Circuit, transistor 204 and diode 203, limit the voltage on the pad 200. In some implementations, an input resistor 205 and additional diodes 206, 207 are provided. One or more ESD capacitor 210 is provided across the input diode 207 to increase ESD protection by slowing down the increase of voltage on the I/O pad 200 during and ESD event, providing extra time for the Protection Circuit to react. An exemplary structure for an INTEGRATED CIRCUIT WITH MOS CAPACITOR FOR IMPROVED ESD PROTECTION is shown by Strauss in U.S. Pat. No. 5,264,723, issued Nov. 23, 1993, incorporated herein by reference.

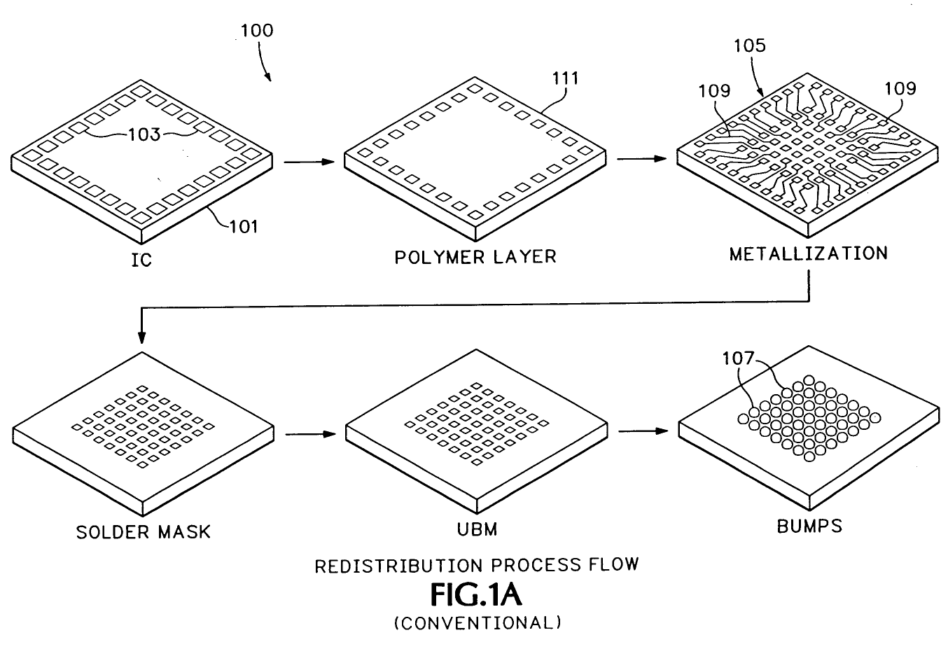

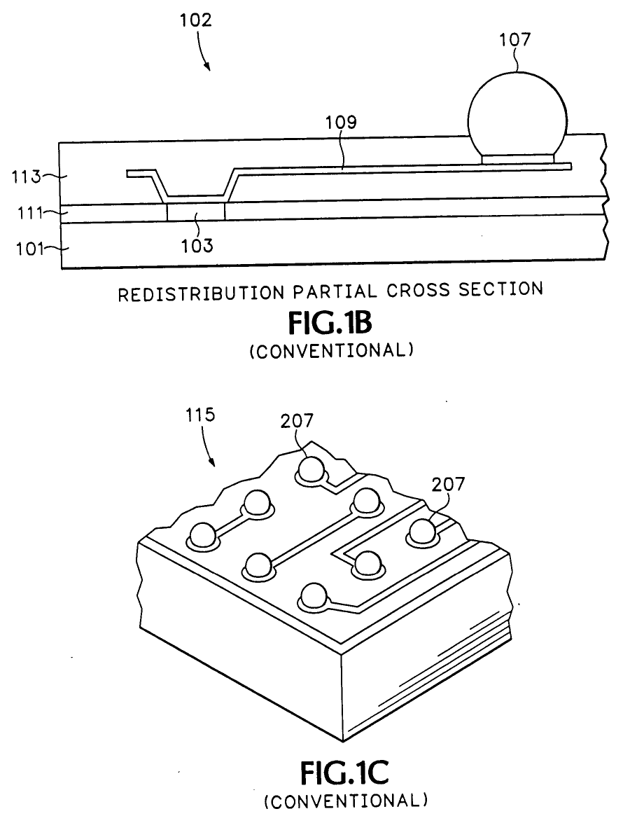

FIG. 3 in accordance with a first exemplary embodiment of the present invention is an elevation view schematic diagram for a WLP integrated circuit device. An ESD Capacitor 310, such as shown for the I/O circuit of FIG. 2 as analogous capacitor element 210, is integrated with bump-out beam 109 elements of the packaging. In the prior art it is known to implement an entire ESD capacitor structure 210 wherein both the capacitor plates are within the die 101. In accordance with the present invention a “top” (directionality will be recognized by those skilled in the art as relative for actual implementations) capacitor plate 109c is formed by using a region of the WLP bump-out beam 109 itself. An electrically-grounded “bottom” capacitor plate 309 of a conductive material, e.g., metal, is formed under the passivation layer 111 and the exemplary polyimide layer 113 of the chip-scale packaging. An appropriate lead 307 to ground is connected to the bottom plate 309, e.g., through the normal top level interconnect of the chip to the circuit die ground (shown as the conventional electrical ground symbol). In this exemplary implementation, the capacitor 310 dielectric is made up of a composite of the polyimide file 113 and the passivation layer 111. Other implementations may be constructed. For example, alternatively, the polyimide masking step (see FIG. 1A, “solder mask”) may be adapted in a known manner to remove polyimide in the capacitor dielectric region, leaving only the passivation layer 111 material. Still another exemplary implementation for processing such a capacitor structure would be to open the IC wafer passivation mask but not the polyimide mask so that the capacitor 310 would have a polyimide-only dielectric. Moreover, it should be recognized that other implementations for using bump-out beam 109 metal as a top plate(s) for a capacitor(s) using the process steps as shown in FIG. 1A may be employed leaving out the bump 107 formation to form capacitors for purposes other than I/O ESD protection. This integration of one or more ESD Capacitors 310 into the WLP has a clear advantage of freeing valuable on-chip 101 real estate for other uses.

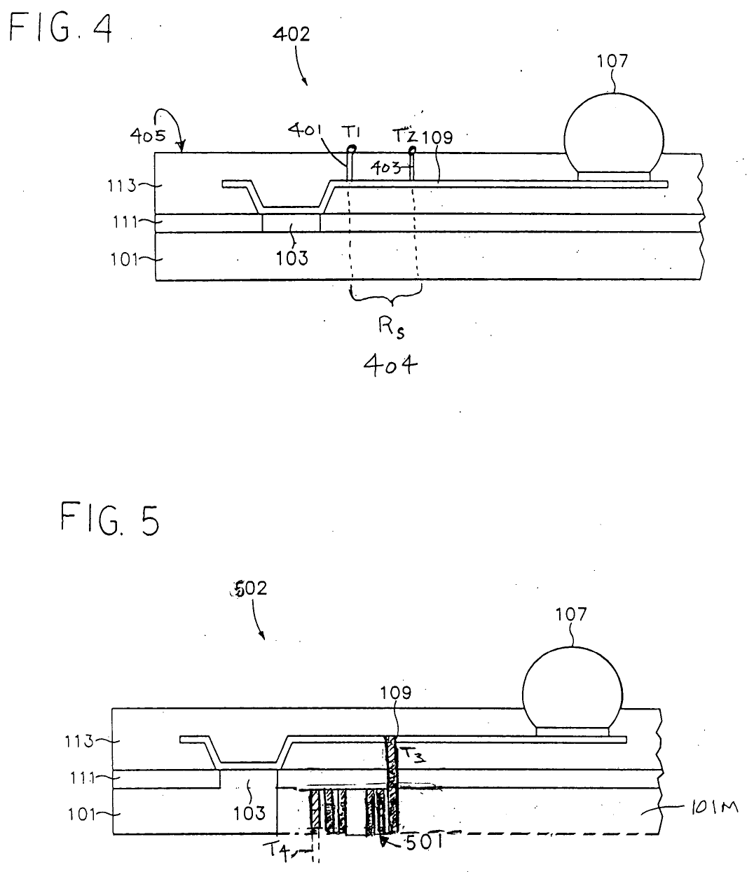

Another embodiment employs the WLP packaging for building a sense resistor as shown in FIG. 4. High current demand apparatus—e.g., battery chargers, welders, motors, and the like—commonly have control circuits using integrated circuits. Control functions measure the current drawn by the apparatus by using a sense resistor at a chip I/O pad. Conventionally, such sense resistors comprise a region of the integrated circuit; for example, see U.S. Pat. No. 4,689,881 to Aleksandravicius et al. (assignors to International Rectifier Corp.), Dec. 3, 2002, for a HIGH CURRENT SENSE RESISTOR AND PROCESS FOR ITS MANUFACTURE, where a low resistance, high current, sense resistor is formed on a semiconductor die using conventional semiconductor processing techniques, incorporated herein by reference.

Again, such a sense resistors use valuable chip real estate. As shown in FIG. 4, a chip-scale structure 402 is provided in accordance with the present invention having a sense resistor 404, R_{S}, for an I/O pad 103 of a chip 101 where chip-scale WLP is employed. A region (see phantom lead lines) of the bump-out beam 109 itself is tapped T1, T2 with two leads 401, 403 leading from the beam to the surface 405 of the package stress absorbing material 113. As would be known in the art, the nature of the beam material and the length and geometric shape of the tapped region will determine the resistance characteristic of the so-fabricated sense resistor 404. A plurality of taps T_{N} may be employed wherein a plurality of sense resistors, R_{S}, can be implemented. For example the resistor might simply be a 100 micron long and 200 micron wide region of the bump-out beam 109; the size and shape of the resistor would be set by the desired nominal resistor value and the resistivity of the material of beam 109. Known manner processes such as laser-trimming might also be employed to achieve a precision resistor geometry. Moreover, a plurality of resistors in parallel might be formed during metallization, but laser-trimming used subsequently to remove interconnections thereof in order to achieve the appropriate value for the specific implementation. While the shown embodiment of FIG. 4 effectively uses the bump 107 as one terminal, it should be recognized that other possible configurations may be implemented; e.g., without a bump-out whereby a large resistor is connected to the subjacent IC components without using valuable chip real estate; or, having the bump 107 as a first resistor terminal and a second terminal within the subjacent chip architecture.

Another desirable IC MOS circuit element is an inductor. A prior art example is shown by Lihui et al., in IEEE Electron Device Letters, Vol. 23, No. 8, August 20002, for a “High Q Multilayer Spiral Inductor on Silicon Chip for 5˜6 GHz.” A chip-scale structure 502 in accordance with the present invention is shown in FIG. 5. As with the capacitor and resistor elements described with respect to FIGS. 3 and 4, the bump-out beam 109 is integrated with an inductor element.

An inductor coil 501, fabricated in a known manner such as in Cu/SiO₂technology, is shown using a small area of the bump-out beam 109 as a first tap T3. A second tap T4 can be through a via from the appropriate chip interconnect point as needed for the specific implementation. A single spiral inductor embodiment is shown constructed in a known manner for top-layer metallization of the chip in section 101M thereof. Multi-spiral coils, such as depicted by Lihui, may be implemented, with appropriate coil-width, spacing, core diameter and shape as needed. This again, as with previous embodiments, frees valuable sub-top metal layer, on-chip real estate for other uses. Again, as with previous embodiments, scaling and geometry will be implementation specific. It should be recognized that since the polyimide layer 111 is relatively thick in the state of the art (e.g., 5-50 microns) and has a lower dielectric constant than most normal IC layers (such as oxide or nitride), that the present invention is particularly valuable for inductor element construction to improve the quality factor, “Q,” by minimizing the deleterious effect of parasitic capacitance of the dielectric between the inductor coils and the interconnect and between the inductor element 501 and the chip underlying top metal 101.

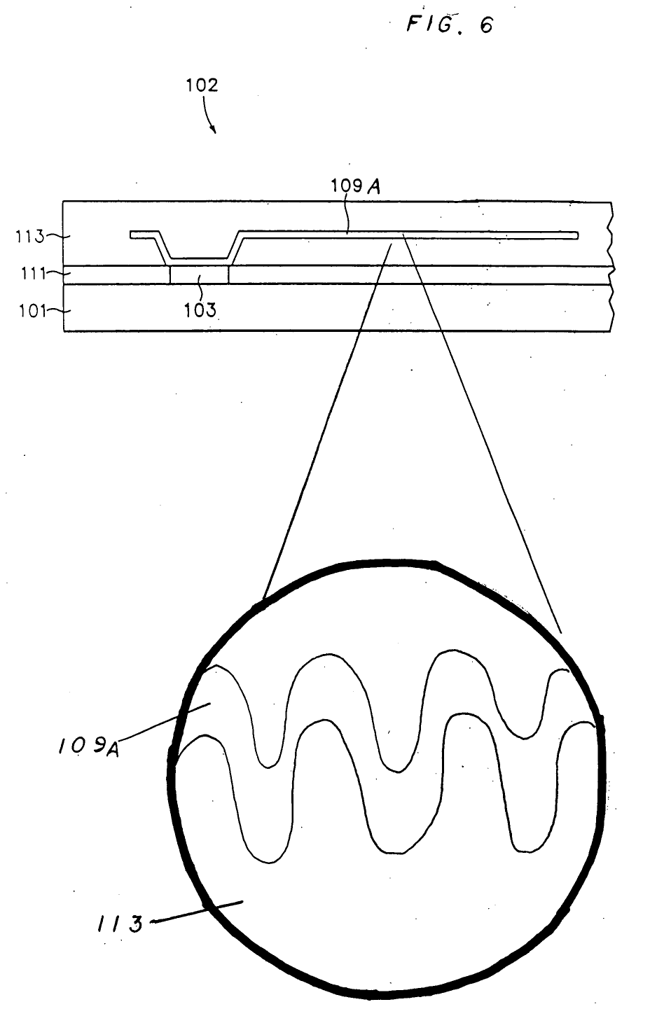

FIG. 6 in accordance with a fourth exemplary embodiment of the present invention is an elevation view schematic diagram, with a rotated, blow-up section, for a chip scale antenna implementation. In this implementation, rather than forming a bump-out beam 109 in the stress-absorbing packaging layer 113, the process (see FIG. 1A) is altered during metallization steps to provide one or more antenna structures 109A. Each antenna 109A can be formed having an appropriate shape and geometry for forming an antenna such as for receiving or transmitting, or both, radio frequency signals. Appropriate connection(s) by metallization layer 101 from the antenna 109A through the via 103 in the passivation layer 111 is provided to underlying components (not shown) of a transceiver chip. The process takes advantage of the relatively thick dielectric packaging material, e.g., polyimide (see FIG. 1, “Polymer layer” 111) providing low parasitic capacitance from the structure. Note that while a meandering-line construction antenna 109A is shown in the rotated (top view), blow up section of FIG. 6, specific geometries can be tailored to specific implementations as needed.

Thus, the present invention provides active circuit elements for semiconductor device I/O pads by integrating chip-scale bump-out beams with the elements. The bump-out beam dielectric encasing material is employed to hold selected components of the active circuit elements such as an inductor coil, a capacitor plate, or resistor taps.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications, combinations of embodiments, and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom. Applicant has made this disclosure with respect to the current state of the art, but also contemplates advancements during the term of the patent, and that adaptations in the future may take into consideration those advancements, in other word adaptations in accordance with the then current state of the art. It is intended that the scope of the invention be defined by the Claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112, sixth paragraph, unless the element is expressly recited using the phrase “means for . . . ” and no method or process step herein is to be construed under those provisions unless the step, or steps, are expressly recited using the phrase “comprising the step(s) of . . . .”

1. An integrated circuit structure comprising:
a circuit die;
at least one input-output pad for connecting to said circuit die;
wafer-level packaging including an electrically conductive material bump-out beam and at least one active circuit element wherein the active circuit element integrates therein at least a segment of said beam.

2-3. Cancelled

4. The structure as set forth in claim 1 comprising:
said beam is encased in a dielectric material, and
said active circuit element is a capacitor having a first plate formed by a predefined region of said beam.

5. The structure as set forth in claim 4 further comprising:
a grounded second plate embedded in said dielectric material of said die proximate said region. +6-8. Cancelled

9. A wafer-level packaged integrated circuit device comprising:
a circuit die having at least one input-output pad and a top metal layer;
a wafer-level package including a dielectric material layer superjacent said die and a conductive material beam encapsulated in said dielectric material layer and leading to a connector bump on an external surface of said dielectric material layer; and
an ESD protection capacitor integrated into said top metal layer, using a predetermined segment of said beam as a first plate and having a grounded second plate embedded in said dielectric material layer proximate said segment.

10-12. Cancelled
